(19) United States
(12) Patent Application Publication
(10) Pub. No.: US 2013/0340678 A1
(43) Pub. Date: Dec. 26, 2013

(54) GAS SUPPLY APPARATUS AND FILM FORMING APPARATUS

(71) Applicant: Tokyo Electron Limited, Tokyo (JP)

(72) Inventors: Yu WAMURA, Oshu-shi (JP); Yusuke TACHINO, Nirasaki City (JP); Akira SHIMIZU, Niraski City (JP)

(21) Appl. No.: 13/925,333

(22) Filed: Jun. 24, 2013

(30) Foreign Application Priority Data
Jun. 25, 2012 (JP) 2012-142063

(51) Int. Cl. C23C 16/455

(52) U.S. Cl. CPC C23C 16/455
USPC 118/712; 137/334

(57) ABSTRACT

Provided is a gas supply apparatus which includes a raw material gas supply system for supplying a raw material gas into a processing container, a tank to store a liquid raw material, a main heating unit for heating the bottom and sides of the tank, a ceiling heating unit for heating a ceiling portion of the tank, a main temperature measurement unit for measuring a temperature of a region of the main heating unit, a ceiling temperature measurement unit for measuring a temperature of the ceiling heating unit, a liquid phase temperature measurement unit for measuring a temperature of the liquid raw material, a vapor phase temperature measurement unit for measuring a temperature of a vapor phase portion in the upper part of the tank, a level measurement unit for measuring a liquid level of the liquid raw material, and a temperature control unit for controlling the heating units.

### CROSS-REFERENCE TO RELATED APPLICATION

This application claims the benefit of Japanese Patent Application No. 2012-142063, filed on Jun. 25, 2012, in the Japan Patent Office, the disclosure of which is incorporated herein in its entirety by reference.

### TECHNICAL FIELD

The present disclosure relates to an apparatus for forming a thin film on a surface of an object to be processed such as a semiconductor wafer, and a gas supply apparatus used thereto.

### BACKGROUND

In general, in manufacturing a semiconductor integrated circuit, a variety of processes including a film forming process, an etching process, an oxidation process, a diffusion process, a modification process, a removal process of native oxide film and the like are performed on a semiconductor wafer such as a silicon substrate. Such processes are performed by a single type processing apparatus for processing wafers one by one or a batch type processing apparatus for processing a plurality of wafers at a time. For example, when these processes are performed by a vertical type processing apparatus, so-called the batch type processing apparatus, first, semiconductor wafers from a cassette capable of accommodating a plurality of, e.g., 25 sheets of wafers, are transferred to and loaded into a vertical wafer boat and then supported therein in a multistage manner.

The wafer boat can load, for example, about 30 to 150 sheets of wafers although the number of wafers may vary according to the size of a wafer. The wafer boat enters (is loaded into) an evacuatable processing container from below, while the inside of the processing container is air-tightly maintained. Then, while controlling various process conditions such as a flow rate of the processing gas, the process pressure, the process temperature are controlled, a predetermined heat treatment is performed.

For the film forming process as an example, recently, in terms of improving properties of a semiconductor integrated circuit, a variety of metal materials tend to be used. For example, metal materials, such as zirconium (Zr) and ruthenium (Ru), which have not been used in a conventional method of manufacturing a semiconductor integrated circuit, are used. In general, such metals are combined with an organic material into a liquid organic metal material, which is used as a raw material. The raw material is stored in a raw material storage tank, a container kept airtight, and heated to generate a raw material gas. The raw material gas is saturated in the raw material storage tank and is delivered by a carrier gas made of, e.g., a rare gas such that it is used in the film forming process or the like.

However, recently, the diameter of a semiconductor wafer W has increased. For example, the diameter of a wafer is due to be further increased from 300 mm up to 450 mm in the future. Also, a large amount of raw material gas is required to be flown because a capacitor insulating film of DRAMs having a high aspect ratio structure needs to be formed to achieve good step coverage in association with the device miniaturization or an increase of the throughput of a film forming process.

In this case, a thermocouple for measuring a temperature is disposed in the raw material storage tank. Based on a measurement of the thermocouple, an amount of power to be supplied to a heater of the raw material storage tank is adjusted to control the temperature of the liquid raw material, thus controlling a flow rate of generated raw material gas.

However, since a heat capacity of the raw material storage tank is generally relatively large, when a temperature of a sidewall of the raw material storage tank is measured, there is a difficulty in providing highly-responsive control for a temperature of the liquid raw material, which is varied by evaporation heat generated when the liquid raw material is vaporized. In addition, when the heater is controlled based on the measurement of the thermocouple disposed in the liquid raw material, if a difference between a set temperature and the temperature of the liquid raw material is large, excessive power is applied to the heater, which causes pyrolysis of the liquid raw material. Conversely, if the difference between the set temperature and the temperature of the liquid raw material is small, there is a difficulty in providing highly-responsive control for a change in liquid level temperature by the evaporation heat. In addition, with poor responsive control for the temperature of the liquid raw material, an amount of generated raw material gas may be varied depending on a change of the liquid raw material, which may result in poor reproducibility of the film forming process.

### SUMMARY

Some embodiments of the present disclosure provide a gas supply apparatus and a film forming apparatus used thereto, which are capable of providing highly-responsive control for a liquid raw material temperature varied by evaporation heat or the like, while stably maintaining an amount of generated raw material gas regardless of a change in a liquid level of the liquid raw material.

According to one embodiment of the present disclosure, there is provided a gas supply apparatus equipped with a processing container for performing a film forming process for an object to be processed. The gas supply apparatus includes a raw material gas supply system configured to supply a raw material gas carried with a carrier gas into the processing container, a raw material storage tank having a gas inlet for introducing the carrier gas and a gas outlet connected to a gas passage through which the raw material gas carried with the carrier gas flows, and configured to store a liquid raw material, and a main heating unit configured to heat a bottom and sides of the raw material storage tank to generate the raw material gas. Further, the gas supply apparatus includes a ceiling heating unit configured to heat a ceiling portion of the raw material storage tank, a main temperature measurement unit configured to measure a temperature of a region in which the main heating unit is disposed, and a ceiling temperature measurement unit configured to measure a temperature of a region in which the ceiling heating unit is disposed. Also, the gas supply apparatus includes a liquid phase temperature measurement unit configured to measure a temperature of the liquid raw material stored in the raw material storage tank, a vapor phase temperature measurement unit configured to measure a temperature of a vapor phase portion in the upper part of the raw material storage tank, a level measurement unit configured to measure a liquid level of the liquid raw material, and a temperature control unit configured to control the main heating unit and the ceiling heating unit. In the gas supply apparatus, the temperature control unit is operated to perform a first process of determining whether to proceed to a second process based on a measurement of the main temperature measurement unit, a measurement of the liquid phase measurement unit, and a predetermined set temperature, and, if it is determined not to proceed to the second process, controlling the main heating unit and the ceiling heating unit based on the set temperature, and the second process of obtaining a control temperature based on measurements of the main temperature measurement unit, the liquid phase temperature measurement unit, the vapor phase temperature measurement unit and the level measurement unit, and controlling the main heating unit and the ceiling heating unit based on the control temperature.

According to another embodiment of the present disclosure, there is provided a film forming apparatus for performing a film forming process for an object to be processed. The film form apparatus includes an evacuatable processing container, a holding unit configured to hold the object to be processed within the processing container, and a heating unit configured to heat the object to be processed. The film form apparatus further includes a gas supply apparatus as described above.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a longitudinal sectional view showing one example of a film forming apparatus according to some embodiments.

FIG. 2 is an enlarged view of a raw material storage tank of a raw material gas supply system.

FIG. 3 is a block diagram showing one example of a flow of temperature control.

FIG. 4 is a graphical view of one example of a temperature difference between measurements of a liquid phase temperature measurement unit and a vapor phase temperature measurement unit with respect to a change in liquid level while a raw material is being supplied.

FIG. 5 is a flow chart showing an outline of a control process of a temperature control unit.

FIG. 6 is a flow chart showing a first process.

FIG. 7 is a flow chart showing a second process.

FIGS. 8A and 8B are graphical views of evaluation results for a gas supply apparatus according to an embodiment of the present disclosure

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

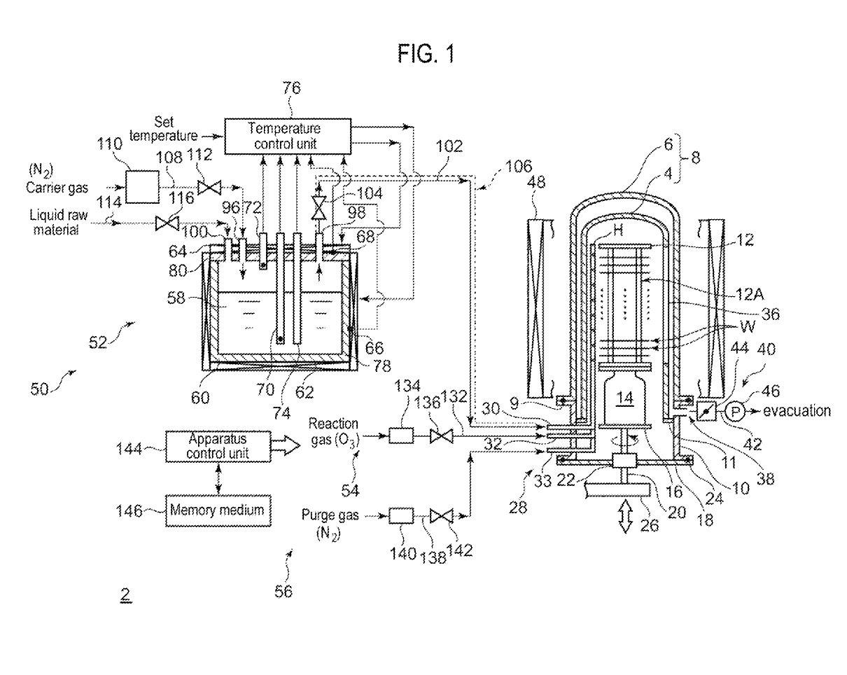

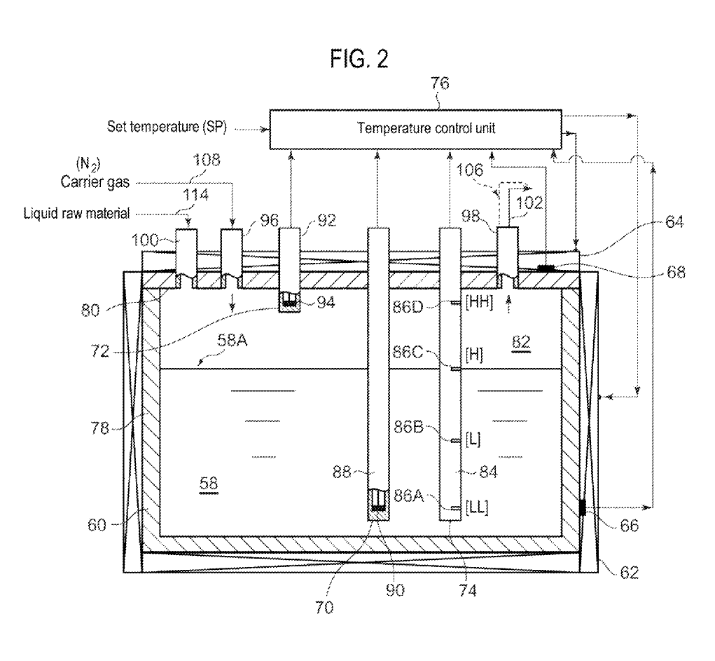

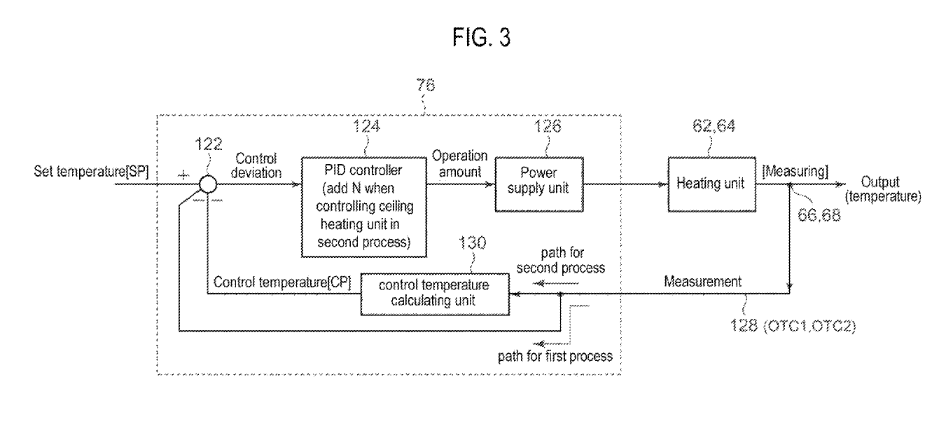

A gas supply apparatus and a film forming apparatus according to one embodiment of the present disclosure will now be described in detail with reference to the accompanying drawings. FIG. 1 is a longitudinal sectional view showing one example of a film forming apparatus according to one embodiment of the present disclosure, FIG. 2 is an enlarged view of a raw material storage tank of a raw material gas supply system, and FIG. 3 is a block diagram showing one example of a flow of temperature control.

As shown, the film forming apparatus 2 includes a processing container 8 of a double-container structure which is provided with a cylindrical inner container 4 having a ceiling and a cylindrical outer container 6 concentrically arranged outside thereof and having a dome-shaped ceiling. Both the inner container 4 and the outer container 6 are made of a heat resistant material, for example, quartz. A lower end of the processing container 8 is connected to and supported by a cylindrical manifold 10 made of, for example, stainless steel, via a sealing member 9 such as an O-ring. A lower end of the inner container 4 is supported on a support ring 11 mounted to the inner wall of the manifold 10. Alternatively, the film forming apparatus 2 may be configured to include a circular cylindrical processing container of quartz without installing the manifold 10 of stainless steel.

The manifold 10 is molded in a shape of a circular cylindrical body. A wafer boat 12 made of quartz, which is a holding unit for loading a plurality of semiconductor wafers W (objects to be processed) in a multistage manner, is configured to be vertically inserted into or separated from the manifold 10 through the bottom thereof. In this embodiment, a plurality of pillars 12A of the wafer boat 12 are allowed, for example, about 50 to 150 wafers W having a diameter of 300 mm, to be supported thereon in a multistage manner at an approximately regular pitch.

The wafer boat 12 is placed on a table 16 via a thermos container 14 of quartz. The table 16 is supported on a rotating shaft 20 which penetrates a lid part 18 made of, for example, stainless steel, for opening/closing a lower end opening of the manifold 10. In addition, the portion penetrated by the rotating shaft 20 is fitted with, e.g., a magnetic fluid seal 22, and air-tightly seals and rotatably supports the rotating shaft 20. In addition, a sealing member 24 such as an O-ring is interposed and installed in a periphery of the lid part 18 and the lower end of the manifold 10 so that a sealing property of the processing container 8 is maintained.

The rotating shaft 20 is mounted to a leading end of an arm 26 supported by an elevating mechanism (not shown) such as a boat elevator and is configured to elevate the wafer boat 12, the lid part 18 and so on together so that they can be inserted into and separated from the processing container 8. In addition, with the table 16 fixed to the lid part 18, the wafers W may be processed without rotating the wafer boat 12. The processing container 8 is fitted with a gas introduction part 28 for introducing a processing gas.

Specifically, in this embodiment, the gas introduction part 28 has a plurality of gas dispersion nozzles, for example, three gas dispersion nozzles 30, 32 and 33, each of which includes a quartz tube penetrating a sidewall of the manifold 10 inwards, and bent and extending upwards. Each of the gas dispersion nozzles 30, 32 and 33 has a plurality (large number) of gas injection holes H formed along its lengthwise direction to be spaced apart from each other at a predetermined interval, in which the gas injection holes H are allowed to almost uniformly inject gas in the horizontal direction. The three gas dispersion nozzles 30, 32 and 33 are juxtaposed along the circumferential direction of the processing container 4.

On the other hand, an elongated exhaust port 36 is formed in the opposite side of the processing container 8 facing the gas dispersion nozzles 30, 32 and 33 by partially cutting a portion of the sidewall of the inner container 4 off, for example in the vertical direction, in order to exhaust the internal atmosphere of the processing container 8.

Further, a gas outlet 38 in communication with the exhaust port 36 is formed in an upper portion of a sidewall of the support ring 11 of the manifold 10, and the atmosphere in the inner container 4 is discharged into a gap between the inner container 4 and the outer container 6 through the exhaust port 36 and reaches the gas outlet 38. In addition, the gas outlet 38 is fitted with an evacuation system 40. The evacuation system 40 has an exhaust passage 42 connected to the gas outlet 38. The exhaust passage 42 is fitted with a pressure control valve 44 or a vacuum pump 46 to evacuate the processing container 8 while maintaining the inside of the processing container 8 at a predetermined pressure. In addition, a cylindrical heating unit 48 is installed to enclose an outer periphery of the processing container 8, thereby heating the processing container 8 and the wafers W therein.

In addition, a gas supply apparatus 50 according to an embodiment of the present disclosure is provided to supply gas required for the film forming process into the processing container 8. In this embodiment, the gas supply apparatus 50 includes a raw material gas supply system 52 for supplying raw material gas, a reaction gas supply system 54 for supplying reaction gas reacting with the raw material gas, and a purge gas supply system 56 for supplying purge gas. Specifically, the raw material gas supply system 52 has a raw material storage tank 60 to store a liquid raw material 58 including an organic metal material. The raw material storage tank 60 is also called an “ampoule” or “reservoir.”

In this embodiment, examples of the liquid raw material 58 may include ZrCp(NMe₂)₃ [cyclopentadienyl.tris(dimethylamino) zirconium] which is a liquid organic compound of zirconium. The raw material gas supply system 52 includes a main heating unit 62 for heating the bottom and sides of the raw material storage tank 60 to generate the raw material gas, a ceiling heating unit 64 for heating the ceiling of the raw material storage tank 60, a main temperature measurement unit 66 for measuring a temperature of a region in which the main heating unit 62 is disposed, a ceiling temperature measurement unit 68 for measuring a temperature of a region in which the ceiling heating unit 64 is disposed, a liquid phase temperature measurement unit 70 for measuring a temperature of the liquid raw material 58, a vapor phase temperature measurement unit 72 for measuring a temperature of an upper vapor phase portion within the raw material storage tank 60, a level measurement unit 74 for measuring a liquid level of the liquid raw material 58, and a temperature control unit 76 for controlling the main heating unit 62 and the ceiling heating unit 64.

More specifically, the raw material storage tank 60 includes a tank body 78 made of a metal material such as stainless steel and has a cylindrical shape with a bottom, and a ceiling cover 80 made of a metal material such as stainless steel for air-tightly covering a ceiling portion of the tank body 78. The capacity of the raw material storage tank 60 is set to, for example, 1 to 10 litters.

The main heating unit 62 is provided to surround and cover substantially the entire circumference of the bottom and sides of the tank body 78. The ceiling heating unit 64 is provided to cover substantially the entire top surface of the ceiling cover 80. As shown in FIG. 2, the upper part within the raw material storage tank 60 corresponds to the vapor phase portion 82 in which the raw material is stored. The size of the vapor phase portion 82 is varied depending on a vertical variation of the liquid level 58A of the liquid raw material 58. Alternatively, the main heating unit 62 may be provided in a portion of the tank body 78, and the ceiling heating unit 64 may be provided in a portion of the ceiling cover 80.

The main temperature measurement unit 66 is formed of, for example, a thermocouple and is mounted to the circumference of a later portion of the tank body 78 in order to measure a temperature of the tank body 78. The main temperature measurement unit 66 may be positioned below the vertically varied liquid level 58A. In some embodiments, the main temperature measurement unit 66 may be positioned at the lower side of the bottom of the tank body 78. The ceiling temperature measurement unit 68 is formed of, for example, a thermocouple and is mounted to the top side of the ceiling cover 80 in order to measure a temperature of the ceiling cover 80.

As shown in FIG. 2, the level measurement unit 74 has a bar-like level measurement body 84 which is mounted to pass through the ceiling cover 80 and extends into the raw material storage tank 60. A leading end of the level measurement unit 74 is positioned near the bottom of the raw material storage tank 60. In this example, the level measurement body 84 has a plurality of, e.g., four, detection sensors 86A, 86B, 86C and 86D which are arranged substantially even, at regular intervals in the longitudinal direction. Each of the detection sensors 86A, 86B, 86C and 86D detects the presence or absence of the liquid raw material 58, thereby recognizing stepwise positions of the liquid level 58A. Positions of the detection sensors 86A to 86D are denoted by level positions “LL,” “L,” “H” and “HH” in the level measurement body 84 from bottom to top.

For example, if the detection sensor 86A detects the “liquid raw material presence” and the detection sensor 86B detects the “liquid raw material absence,” the liquid level 58A is considered to be positioned between the level positions “LL” and “L.” This measurement of the level measurement unit 74 is sent to both of the temperature control unit 76 and an apparatus control unit which will be described later. An example of the level measurement unit 74 may include an ultrasonic type 4-point liquid level sensor. The level position to be measured is not limited to the above four points but may be detected with more points.

The liquid phase temperature measurement unit 70 includes an elongated hollow sealed sensor tube 88 and a thermocouple 90 disposed at the lower end of the sensor tube 88. The sensor tube 88 is mounted to extend downward through the ceiling cover 80, and its leading end is positioned to be equal to the lowest level position “LL” of the level measurement unit 74. The level position “LL” is controlled such that the liquid raw material 58 always exists, as will be described later, thereby allowing the thermocouple 90 to measure the temperature of the liquid raw material 58 always. The sensor tube 88 is made of a metal such as a stainless steel.

The vapor phase temperature measurement unit 72 includes an elongated hollow sealed sensor tube 92 and a thermocouple 94 disposed at the lower end of the sensor tube 92. The sensor tube 92 is mounted to extend downward through the ceiling cover 80, and its leading end is positioned to be equal to the highest level position “HH” of the level measurement unit 74. The level position “HH” is controlled such that the raw material gas always exists, as will be described later, thereby allowing the thermocouple 94 to measure the temperature of the raw material gas of the vapor phase portion 82 always. The sensor tube 92 is made of metal such as stainless steel.

In this example, the liquid raw material 58 is heated to a temperature (for example, 80 to 160 degrees C.) at which it is heated to a temperature range in which the liquid raw material 58 is not pyrolized, in order to generate the raw material gas. The ceiling cover 80 is provided with a gas inlet 96 into which a carrier gas carrying the raw material gas is introduced and a gas outlet 98 from which the raw material gas is discharged with the carrier gas. The ceiling cover 80 is further provided with a raw material inlet 100 into which the liquid raw material is introduced.

In addition, a gas passage 102 is provided to connect the gas outlet 98 to the gas dispersion nozzle 30 out of the gas dispersion nozzle 30, 32 and 33 of the gas introduction part 28 in the processing container 8. An opening/closing value 104 (see FIG. 1) to control a flow of the raw material gas is disposed in the middle of the gas passage 102. Along the gas passage 102, a passage heater 106 such as a tape heater is disposed to heat the gas passage 102 to, for example, 85 to 165 degrees C., which prevents the raw material gas from being liquefied.

In addition, a carrier gas passage 108 for introducing the carrier gas into the raw material storage tank 60 is connected to the gas inlet 96 of the ceiling cover 80. In the middle of the carrier gas passage 108, a flow rate controller 110 such as a mass flow controller for controlling a gas flow rate and an opening/closing value 112 are disposed in this order from upstream to downstream (see FIG. 1). The carrier gas is fed with a high pressure of, for example, about 2.5 kg/cm². In this embodiment, nitrogen gas is use as the carrier gas, but is not limited thereto. For example, a rare gas such as, for example, Ar, He or the like may be used as the carrier gas. In addition, a raw material passage 114 with an opening/closing value 116 disposed in its middle is connected to the raw material inlet 100 in order to supplement the liquid raw material 58 in the raw material storage tank 60 if it is insufficient.

The temperature control unit 76 may be implemented with, for example, a microcomputer or the like, and is configured to perform a first process of controlling the main heating unit 62 and the ceiling heating unit 64 based on an input set temperature, a measurement of the main temperature measurement unit 66 and a measurement of the liquid phase temperature measurement unit 70, and a second process of obtaining a control temperature based on measurements of the measurement units 66, 72 and 74 and controlling the main heating unit 62 and the ceiling heating unit 64 based on the control temperature. A signal flow at that time is shown in a block diagram of FIG. 3. This block diagram shows a schematic signal flow and will be described as a whole since this is essentially used in common to the main heating unit 62 and the ceiling heating unit 64.

The temperature control unit 76 includes a comparator 122 for obtaining a control deviation which is a difference between the set temperature and the control temperature or the measurement, a PID (Proportional Integral Derivative) controller 124 for obtaining an operation amount used to perform a PID control based on the control deviation, and a power supply unit 126 for outputting power to be supplied to various heating units such as the main heating unit 62 and the ceiling heating unit 64 based on the operation amount.

A feedback path 128 of the temperature control unit 76 is used to introduce measurements of the main temperature measurement unit 66 and the ceiling temperature measurement unit 68 and is divided into two branches; one for the first process and the other for the second process in which a control temperature calculating unit 130 for calculating the control temperature is disposed.

Referring to FIG. 1 again, the reaction gas supply system 54 includes a reaction gas passage 132 connected to the gas dispersion nozzle 32. In the middle of the reaction gas passage 132 are disposed a flow rate controller 134 such as a mass flow controller and an opening/closing valve 136 in this order. The flow rate controller 134 and the opening/closing valve 136 are configured to supply the reaction gas while controlling its flow rate as necessary.

An example of the reaction gas may include oxidation gas, for example ozone (O₃), and allows a zirconium oxide film to be formed by oxidizing a Zr-containing raw material. The purge gas supply system 56 includes a purge gas passage 138 connected to the gas dispersion nozzle 33. In the middle of the purge gas passage 138, a flow rate controller 140 such as a mass flow controller and an opening/closing valve 142 are disposed in this order. The flow rate controller 140 and the opening/closing valve 142 are configured to supply the purge gas while controlling its flow rate as necessary. An example of the purge gas may include inert gas such as N₂ gas.

The overall operation of the film forming apparatus 2 configured as above is controlled by an apparatus control unit 144 implemented with, for example, a computer, and a computer program to execute the operation is stored in a memory medium 146. The memory medium 146 may be implemented with, for example, a flexible disk, a compact disc (CD), a hard disk, a flash memory or a DVD. Specifically, the start or stop of the supply, the control of the flow rate of each gas, the control of the process temperature or pressure, the control of a supply of the liquid raw material and the like are performed by commands from the apparatus control unit 144. The temperature control unit 76 is also operated under the control of the apparatus control unit 144.

Next, a method of forming a film using the film forming apparatus 2 configured as above will be described with reference to FIGS. 1 to 7. Here, a case where a zirconium oxide film is formed using tris(dimethylamino)cyclopentadienyl zirconium[C₁₁H₂₃N₃Zr] as the raw material and ozone, which is an oxidation gas, as the reaction gas will be described as an example.

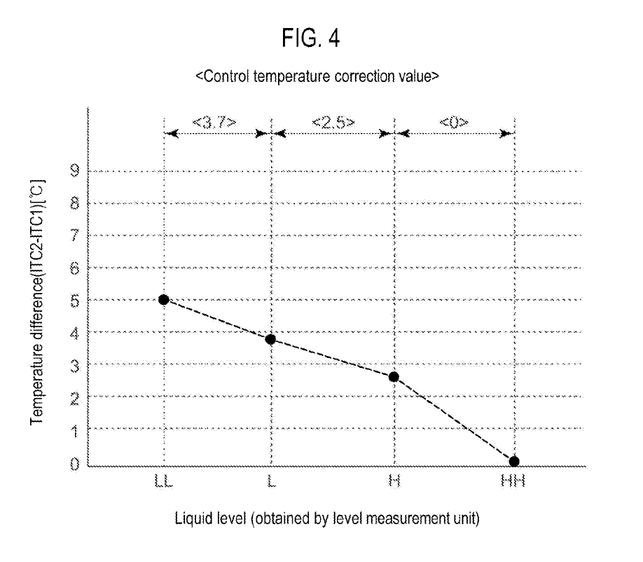

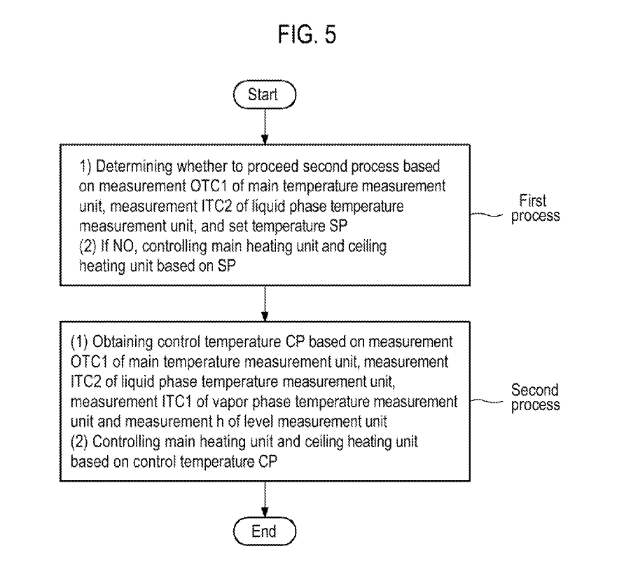

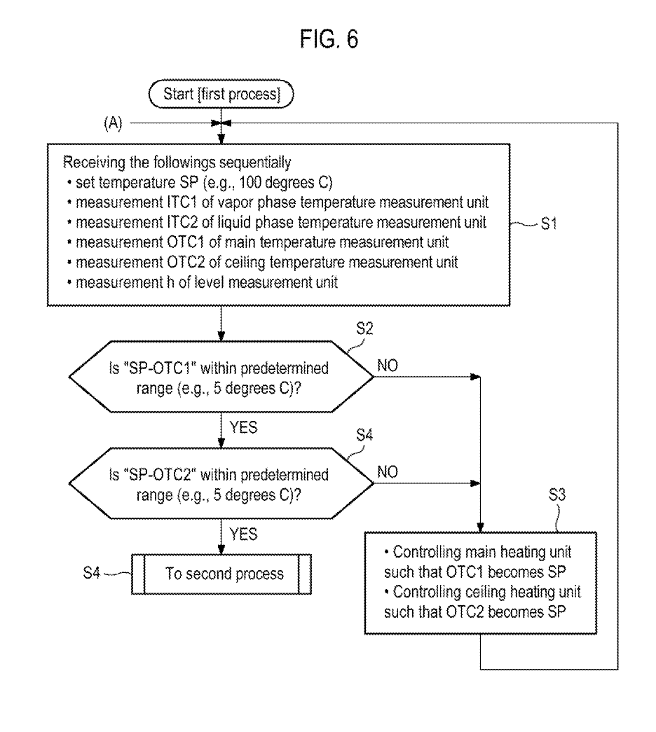

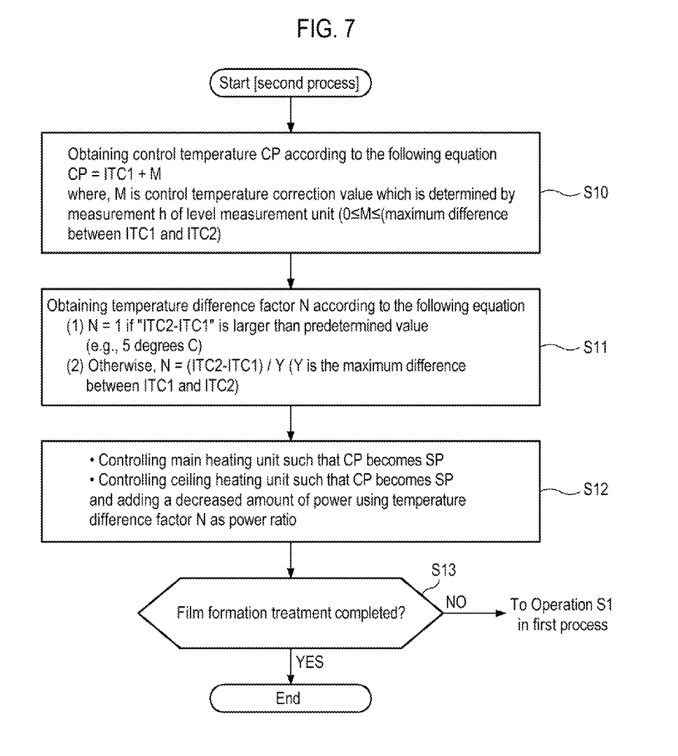

FIG. 4 is a graphical view showing one example of a temperature difference between measurements of the liquid phase temperature measurement unit 70 and the vapor phase temperature measurement unit 72 with respect to a change in the liquid level 58A while the raw material is being supplied, FIG. 5 is a flow chart showing an outline of a control process of the temperature control unit 76, FIG. 6 is a flow chart showing the first process, and FIG. 7 is a flow chart showing the second process. FIG. 4 shows also one example of a control temperature correction value according to an embodiment of the present disclosure.

Specifically, the thin film is formed by repeating one cycle more than once, which consists of a supply operation of alternately supplying the raw material gas and the reaction gas (ozone) in a pulse shape for a certain supply period and a stop operation of stopping the supply.

When the raw material gas is supplied, in the raw material gas supply system 52, the liquid raw material 58 is vaporized and saturated in the raw material storage tank 60 by being heated, and the carrier gas having its flow rate controlled is supplied into the raw material storage tank 60 via the gas inlet 96, whereby the saturated raw material gas carried by the carrier gas flows out of the gas outlet 98 toward the gas passage 102. Then, the raw material gas carried together with the carrier gas is injected from the gas dispersion nozzle 30 disposed in the processing container 8 to be supplied into the processing container 8.

When the reaction gas is supplied, in the reaction gas supply system 54, the reaction gas having its flow rate controlled is flown into the gas passage 132, and the reaction gas is injected from the gas dispersion nozzle 32 to be supplied into the processing container 8. When the purge gas is supplied, in the purge gas supply system 56, the purge gas having its flow rate controlled is flown into the gas passage 138, and the purge gas is injected from the gas dispersion nozzle 33 to be supplied into the processing container 8.

The gas supplied into the processing container 8 flows between the respective wafers W in the transverse direction (horizontal direction) while being brought into contact with the respective wafers W and is introduced into a gap between the inner container 4 and the outer container 6 via the exhaust port 36. The gas also flows down within the gap and then is discharged out of the processing container 8 by means of the evacuation system 40 through the gas outlet 38.

In a practice sequence, first, the wafer boat 12 having, a plurality of (e.g., 50 to 150) 300 mm-sized wafers W mounted thereon at room temperature is loaded into the processing container 8 having a predetermined temperature in advance by being lifted up from the bottom thereof. Then, the processing container 8 is sealed by closing the lower end opening of the manifold 10 in the lid part 18.

Then, the processing container 8 is evacuated to maintain a pressure therein at 0.1 to 3 torr, and at the same time, the power to be supplied to the heating unit 48 is increased to raise the wafer temperature and maintain the process temperature, for example, 250 degrees C. or so. Then, the raw material gas supply system 52 and the reaction gas supply system 54 of the gas supply apparatus 50 are driven, so that as described above, the raw material and the ozone gas are alternately supplied into the processing container 8 and thin films of zirconium oxide are laminated on the surfaces of the wafers W.

At the start of the film forming process (thermal treatment), a raw material gas supply process is performed, in which the raw material gas within the raw material storage tank 60 is first allowed to flow together with the carrier gas into the processing gas. This process allows the raw material gas to be adhered to the surfaces of the wafers W. Here, the carrier gas has a flow rate in a range of 2 to 15 slm, for example, 7 slm, and the gas is allowed to flow, for example, a time in a range of 1 to 10 seconds, which is just a short time.

Next, under the condition where the supply of the carrier gas and the raw material gas is stopped, a purge process of removing residual gas within the processing container 8 is performed. In this purge process, the residual gas in the processing container 8 may be removed by stopping the supply of all of the gases, and the purge gas consisting of an inert gas such as N₂ gas may be supplied into the processing container 8 to substitute for the residual gas, or the combination thereof may be possible. Here, the N₂ gas having a flow rate in a range of 0.5 to 15 slm, for example, 10 slm. This purge process is performed for a time interval of 4 to 120 seconds.

Next, a reaction gas supplying process is performed. Here, the reaction gas supply system 54 is used to supply the reaction gas consisting of ozone into the processing container 8. This process allows the raw material gas adhered to the surfaces of the wafers W to react with the ozone to form a thin film of a zirconium oxide. A process time for this reaction gas supplying process of forming the film falls within a range of 50 to 200 seconds.

If the reaction gas supplying process is terminated, a purge process of removing the residual gas in the processing container 8 is performed. Thus, the above-described respective processes are repeatedly performed predetermined number of times, whereby a thin film of zirconium oxide is laminated.

The series of operations in the film forming process has been illustrated in the above. Next, the start of the film forming process and the temperature control of the raw material gas supply system 52 in the raw material storage tank 60 will be described in more detail. It is assumed that a measurement of the vapor phase temperature measurement unit 72 is “ITC1,” a measurement of the liquid phase temperature measurement unit 70 is “ITC2,” a measurement of the main temperature measurement unit 66 is “OTC1,” a measurement of the ceiling temperature measurement unit 68 is “OTC2,” and the set temperature is “SP.”

Prior to the start of the film forming process, a relationship between the liquid level 58A and a temperature characteristic in the raw material storage tank 60 is obtained. Here, under a condition where the raw material gas is generated and carried together with the carrier gas, a relationship between the liquid level 58A of the liquid raw material 58 and a temperature difference between the measurement “ITC2” of the liquid phase temperature measurement unit 70 and the measurement “ITC1” of the vapor phase temperature measurement unit 72 is obtained. In addition, the liquid raw material is heated with the set temperature SP set to, for example, 100 degrees C., and the relationship thereof is shown in FIG. 4. It can be seen from FIG. 4 that the temperature difference increases sequentially from “0 degree C”, through “2.5 degrees C.” and “3.7 degrees C.,” to “5 degrees C.” as the liquid level 58A decreases from “HH” to “LL.”

That is, the maximum temperature difference between ITC2 and ITC1 is set to “5 degrees C.” in this example. It is assumed that this maximum temperature difference is directly used as a control temperature correction value. As described above, the reason for the temperature difference between ITC2 and ITC1 depending on the liquid level 58A is that a thermal conductivity of the vapor phase portion 82 (in which the raw material gas is stored) is considerably smaller than that of the liquid phase (or the liquid raw material).

For example, the control temperature correction value decreases sequentially to a value below the maximum temperature difference and the temperature difference is set to “3.7” if the liquid level 58A is between “LL” and “L,” “2.5” if the liquid level 58A is between “L” and “H,” and “0” if the liquid level 58A is between “H” and “HH.” In addition, the maximum temperature difference, 5 degrees C., between ITC 2 and ITC1 is merely one example. It is to be understood that the maximum temperature difference may be changed depending on the capacity of the raw material storage tank 60, the kind of the liquid raw material, etc., and, in which case, the control temperature correction value is changed with the change in the maximum temperature difference.

However, in a practice film forming process, the supply of the raw material gas is performed as follows under the control of the temperature control unit 76. At the start of the film forming process, the temperature control unit 76 is operated to perform a first process of determining whether to proceed to a second process based on a measurement OTC1 of the main temperature measurement unit 66, a measurement ITC of the liquid phase measurement unit 70, and the predetermined set temperature SP, and, if it is determined not to proceed to the second process, controlling the main heating unit 62 and the ceiling heating unit 64 based on the set temperature SP; and the second process of obtaining a control temperature CP based on measurements OTC1, ITC2, ITC1 and h of the main temperature measurement unit 66, the liquid phase temperature measurement unit 70, the vapor phase temperature measurement unit 72 and the level measurement unit 74 and controlling the main heating unit 62 and the ceiling heating unit 64 based on the control temperature CP. In addition, the first process is repeatedly performed if it is determined not to proceed to the second process.

That is, as shown in FIG. 5, the first process corresponds to a preparation operation before performing the film forming process and determines whether to proceed to the second based on the measurement OTC1 of the main temperature measurement unit 66, the measurement ITC2 of the liquid phase measurement unit 70, and the set temperature SP. If it is determined not to proceed to the second process, the first process controls the main heating unit 62 and the ceiling heating unit 64 based on the set temperature SP and is repeatedly performed until proceeding to the second process.

The first process will be now described in more detail with reference to FIG. 6. At the start of the film forming process, the first process is performed as the preparation operation, in which the set temperature SP, the measurement ITC1 of the vapor phase temperature measurement unit 72, the measurement ITC2 of the liquid phase temperature measurement unit 70, the measurement OTC1 of the main temperature measurement unit 66, the measurement OTC2 of the ceiling temperature measurement unit 68 and the measurement h of the level measurement unit 74 are first sequentially received (Operation S1). The “SP” is set to, for example, 100 degrees C. The measurements ITC1 and h not used in the first process may be received after proceeding to the second process.

Next, in operation S2, it is determined whether or not a temperature difference “SP-OTC1” falls within a predetermined range, for example, 5 degrees C. This predetermined range of “5 degrees C.” is obtained based on a control start temperature, for example by the PID (Proportional Integral Derivative) control, which will be described later. For example, the PID control has a proportional band of a preset percentage (%) for a set value of P (proportion) and, in the proportional band, an operation amount is controlled to be slowly decreased in proportion to a deviation. In this example, the “5 degrees C.” corresponds to the proportional band. If the temperature difference is larger than 5 degrees C. (NO in operation S2), this means that the raw material storage tank 60 has not yet sufficiently been heated, and accordingly, the process proceeds to operation S3 where heating-up is accelerated by controlling the main heating unit 62 to receive much power such that the OTC1 becomes “SP,” i.e., 100 degrees C. and, at the same time, controlling the ceiling heating unit 64 to receive much power such that the OTC2 becomes “SP,” i.e., 100 degrees C. Thereafter, the process returns to operation S1.

The control of the first process is performed as shown in FIG. 3. Specifically, outputs (temperatures) of the main heating unit 62 and the ceiling heating unit 64 are measured by the main temperature measurement unit 66 and the ceiling temperature measurement unit 68, respectively, and the respective measurements OTC1 and OTC2 are input to the comparator 122 via a path for the first process of the feedback path 128. In the comparator 122, control deviations, which are a difference between the measurement OTC1 and the set temperature SP and a difference between the measurement OTC2 and the set temperature SP, are obtained and sent to the PID controller 124. The PID controller 124 calculates an operation amount based on the control deviations provided from the comparator 122, and controls the power supply unit 126 to supply power corresponding to each of the main heating unit 62 and the ceiling heating unit 64 based on the operation amount.

On the other hand, it is determined that the temperature difference “SP-OTC1” falls within 5 degrees C. (YES in operation S2), the process proceeds to operation S4 where it is determined whether or not a temperature difference “SP-ITC2” falls within a predetermined range, for example, 5 degrees C. This predetermined range of “5 degrees C.” is the same as that in operation S2. If the temperature difference is larger than 5 degrees C. (NO in operation S4), this means that the liquid raw material 58 has not yet sufficiently been heated, and accordingly, the process proceeds to operation S3 where heating-up is accelerated by controlling the main heating unit 62 to receive much power such that the OTC1 becomes “SP,” i.e., 100 degrees C. and, at the same time, controlling the ceiling heating unit 64 to receive much power such that the OTC2 becomes “SP,” i.e., 100 degrees C.

If it is determined that the temperature difference “SP-ITC2” falls within 5 degrees C. (YES in operation S4), this means that both the raw material storage tank 60 and the liquid raw material 58 are sufficiently heated to generate a sufficient amount of raw material gas and, accordingly, the process proceeds to the second process (in operation S5). In addition, in the first process, the raw material gas carried with the carrier gas may be disused through a disuse channel (not shown) without passing through the processing container 8.

Next, in the second process, the generated raw material gas, together with carrier gas, is introduced into the processing container 8 such that the film forming process is actually performed. In the second process, the control temperature CP is obtained based on the measurements (OTC1, ITC2, ITC1 and h) of the main temperature measurement unit 66, the liquid phase temperature measurement unit 70, the vapor phase measurement unit 72 and the level measurement unit 74. Then, the main heating unit 62 and the ceiling heating unit 64 are controlled based on the control temperature CP. In this case, as will be described later, for the ceiling heating unit 64, an operation amount is limited by a temperature difference factor N under a certain condition in order to prevent the ceiling heating unit 64 from being excessively driven.

In the second process, specifically, as shown in FIG. 7, the control temperature CP is first obtained in operation S10 according to the following equation.

CP=ITC1+M

where, M is a control temperature correction value.

The “M” is determined by the measurement h of the level measurement unit 74 and is set as “0≦M≦(the maximum difference between ITC1 and ITC2).” Here, this maximum difference is set to “5 degrees C.,” as shown in FIG. 4. As described above, the control temperature correction value M is set to “3.7” if the liquid level 58A is between “LL” and “L,” “2.5” if the liquid level 58A is between “L” and “H,” and “0” if the liquid level 58A is between “H” and “HH.” That is, “M” gradually decreases as the liquid level 58A rises.

Next, the process proceeds to operation S11 where the temperature difference factor N is obtained according to the following equation. If a temperature difference “ITC2−ITC1” is larger than a predetermined value, the temperature difference factor N is set to “1.” The predetermined value is, for example, “5 degrees C.” which corresponds to the maximum value of “ITC2−ITC1” shown in FIG. 4.

On the other hand, if the temperature difference “ITC2−ITC1” is equal to or less than the predetermined value, i.e., “5 degrees C.,” the temperature difference factor N is obtained according to the following equation.

N=(ITC2−ITC1)/Y

where, Y is the maximum difference between ITC1 and ITC2 (for example, 5 degrees C.).

In other words, the temperature difference factor N is set to decrease as the difference between ITC1 and ITC 2 decreases. As will be described later, the ceiling cover 80 is prevented from being overheated by decreasing the operation amount for the ceiling heating unit 64 depending on the temperature difference factor N. Thus, after obtaining the temperature difference factor N, the process proceeds to operation S12 where the main heating unit 62 is feedback-controlled such that the control temperature CP becomes equal to the set temperature SP.

Similarly, the ceiling heating unit 64 is feedback-controlled such that the control temperature CP becomes equal to the set temperature SP, such that a decreased amount of power corresponding to the temperature difference factor N as a power ratio is applied to the ceiling heating unit 64 when it is feedback-controlled. Specifically, an amount of power to be applied to the ceiling heating unit 64 in the feedback control is limited by a value of “operation amount×N.”

The control of the second process will now be described with reference to FIG. 3. The outputs (temperatures) OTC1 and OTC2 of the main heating unit 62 and the ceiling heating unit 64 are measured by the main temperature measurement unit 66 and the ceiling temperature measurement unit 68, respectively. When the measurements OTC1 and OTC2 are input to the path for the second process of the feedback path 128, the control temperature CP is obtained in the control temperature calculating unit 130, as described above. Then, instead of the measurements OTC1 and OTC2, a control deviation between the control temperature CP and the set temperature SP is obtained in the comparator 122. Then, the PID controller 124 outputs an operation amount corresponding to the main heating unit 62 based on the control deviation to the power supply unit 126. The power supply unit 126 supplies power corresponding to the operation amount to the main heating unit 62.

Meanwhile, for the ceiling heating unit 64, the PID controller 124 outputs a new operation amount which is obtained by multiplying the temperature difference factor N with a normal operation amount, i.e., “normal operation amount×N” to the power supply unit 126. For N=1, the new operation amount is equal to the normal operation amount. This allows power less than that in the normal operation amount to be applied to the ceiling heating unit 64, which prevents the ceiling cover 80 provided with the ceiling heating unit 64 from being overheated.

For example, if the liquid level 58A with the measurement ITC1 of 95 degrees C. is positioned between “L” and “H,” the control temperature correction value M is “2.5” and, accordingly, the control temperature CP is “95 degrees C.+2.5 degrees C.=97.5 degrees C.” (Operation S10). That is, both the main heating unit 62 and the ceiling heating unit 64 are feedback-controlled such that the control temperature of “97.5 degrees C.” reaches the set temperature of “100 degrees C.” as a target temperature. At this time, if ITC2 is, for example, 99 degrees C., a new operation amount for the ceiling heating unit 64, which amounts to 80% of the normal operation amount, is sent to the power supply unit 126. That is, the temperature difference factor N becomes “(99 degrees C.−95 degrees C.)/5 degrees C=0.8” by an equation “(ITC2−ITC1)/Y” (in operation S11), which results in the temperature difference factor N of 0.8 (80%).

This reduces the power to be supplied to the ceiling heating unit 64 by 20% compared with the normal operation amount, thus preventing the ceiling cover 80 from being overheated. Then, once operation S12 is completed, it is determined whether or not the film forming process has been completed (in operation S13). In operation S13, if NO, the process returns to operation S1 in which the first process is performed, and if YES, the process is ended. The series of treatments are repeatedly performed at a high speed of about 100 msec.

In summary, in the PID control, generally, although 100% of power is always applied to a heater if a difference between the set temperature SP and the control temperature CP is large, the power of the heater is controlled based on a PID value which is determined at the point of time when the control temperature CP approaches the set temperature SP, so that the control temperature CP reaches the set temperature SP. In this case, the aforementioned predetermined range is varied depending on the determined PID value. That is, in this embodiment, if a temperature difference (a difference between the control temperature CP and the set temperature SP) at which the power of the heater is controlled, is established, the process proceeds to the second process. The reason for this is that the first process requires the temperature of the raw material storage tank 60 to be quickly raised to near the set temperature SP and the second process requires the liquid level temperature reduced by the evaporation heat to be quickly raised to the set temperature SP. In this case, if the process proceeds to the second process without passing the first process, an excessive power is applied to the heater so that the liquid raw material 58 is likely to be pyrolized.

With the above-described operation, it is possible to control the temperature of the liquid raw material 58 varied by the evaporation heat with high responsiveness, and stabilize the amount of generated raw material gas regardless of a change in the liquid level 58A of the liquid raw material 58. Accordingly, since the amount of generated raw material gas can be stabilized regardless of the liquid level 58A, as described above, it is possible to improve reproducibility of the film forming process.

### <Evaluation of Inventive Apparatus>

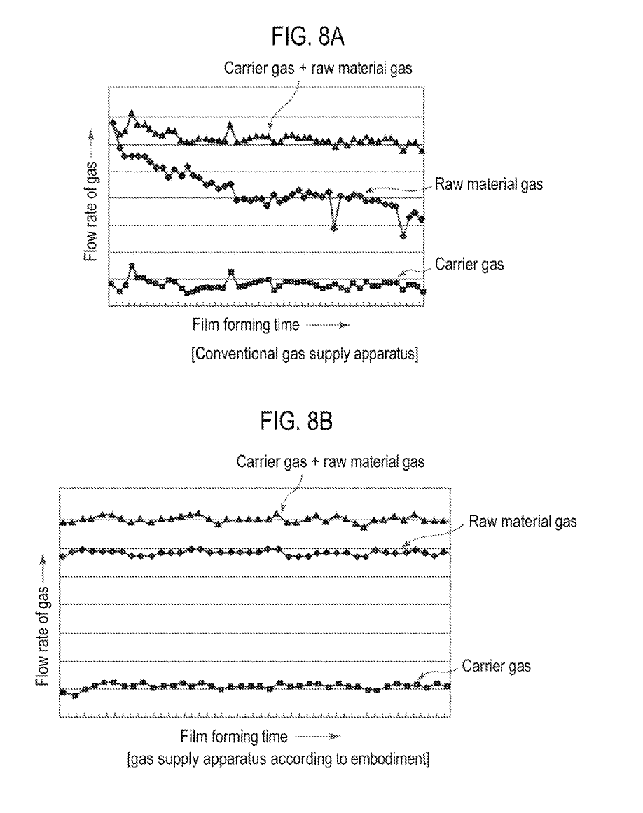

Next, evaluation results of experiments performed for the gas supply apparatus 50 of the present disclosure will be described. In addition, for the purpose of comparison, evaluation experiments for a conventional gas supply apparatus were performed. FIGS. 8A and 8B are graphical representations showing evaluation results for the gas supply apparatus 50 of the present disclosure, FIG. 8A showing a change in a gas flow rate of the conventional gas supply apparatus and FIG. 8B showing a change in a gas flow rate of the gas supply apparatus 50 according to an embodiment of the present disclosure. In these graphs, a horizontal axis represents a film forming time and a vertical axis represents a gas flow rate. In the experiments, a flow rate of a carrier gas and a flow rate of a mixture of the carrier gas and a raw material gas were measured, and a flow rate of the raw material gas was calculated by obtaining a difference between the flow rate of the carrier gas and the flow rate of the mixture.

As can be seen from FIG. 8A, for the conventional gas supply apparatus, the flow rate of the raw material gas gradually decreases as the film forming process is being progressed. In contrast, as can be seen from FIG. 8B, for the gas supply apparatus 50 of the present disclosure, the flow rate of the raw material gas is kept substantially constant as the film forming process is being progressed, and an amount of supplied raw material gas can be stabilized even if the liquid level 58A is varied. While an allowable range of variation of the amount of supplied raw material gas is 5% or less, preferably 3% or less, in general gas supply apparatuses, it has been found that the variation of the amount of supplied raw material gas falls within the allowable range in the gas supply apparatus 50 of the present disclosure.

It is to be understood that, in the above embodiments, the temperature difference of 5 degrees C., the set temperature SP of 100 degrees C., the control temperature correction value M and so on are merely one example without being limited thereto. In some embodiments, the liquid raw material 58 may be properly supplied into the raw material storage tank 60 according to the liquid level 58A when the film forming process is not performed, and the liquid level 58A may be controlled to be positioned between “L” and “H” in the normal operation.

While in the film forming process, the process has been described to return to the first process after the second process is completed, the present disclosure is not limited thereto. Alternatively, the second process may be repeatedly performed after the process proceeds to the second process. In this case, in the second process, the same determination as that in operation S4 of the first process is made to obtain required measurements.

While in the above embodiments, the level measurement unit 74 has been described to detect the liquid levels LL, L, H and HH step by step, the present disclosure is not limited thereto. Alternatively, a level measurement unit capable of measuring the liquid level continuously may be employed. In this case, the control temperature correction value M may be, not stepwise but continuously, set within a range of the maximum difference between ITC1 and ITC2.

While in the above embodiments, ZrCp(NMe₂)₃[cyclopentadienyl.tris(dimethylamino) zirconium] has been described to be used as the liquid raw material 58, the present disclosure is not limited thereto. In some embodiments, one selected from a group consisting of ZrCp(NMe₂)₃[cyclopentadienyl.tris(dimethylamino) zirconium], Zr(MeCp)(NMe₂)₃[methylcyclopentadienyl.tris(dimethylamino) zirconium], Ti(MeCp)(NMe₂)₃[methylcyclopentadienyl.tris(dimethylamino) titanium], tetrakis(dimethylamino) hafnium, trimethylaluminum (TMA), tetrakisdimethylaminohafnium (TDMAH), tetrakisethylmethylaminohafnium (TEMAH), tetrakisethylmethylaminozirconium (TEMAZ) and tetrakisdimethylaminotitanium (TDMAT) may be used as the liquid raw material 58.

Furthermore, in the above embodiments, the oxidation gas, e.g., ozone, has been described to be used as the reaction gas, but other gas including oxygen may be used. Alternatively, a nitridizing gas such as NH₃, a reducing gas such as hydrogen, etc. may be used as the reaction gas depending on a type of process. In addition, while in the above embodiments, the vertical batch type film forming apparatus 2 has been described to be employed as the film forming apparatus, the present disclosure is not limited thereto. In some embodiments, the present disclosure can be naturally applied to a single type film forming apparatus which processes semiconductor wafers one by one.

In addition, although the embodiments have been described using a semiconductor wafer as the object to be treated, the semiconductor wafer includes a compound semiconductor substrate of GaAs, SiC, GaN or the like or a silicon substrate. Furthermore, the present disclosure is not limited to these substrates and may be applied to a glass substrate used in a liquid crystal display, a ceramic substrate, or the like.

According to the present disclosure in some embodiments, it is possible to provide highly-responsive control for a temperature of a liquid raw material varied by evaporation heat or the like, and stabilize an amount of generated raw material gas regardless of a change in a liquid level of the liquid raw material. Therefore, it is possible to improve reproducibility of a film forming process.

While certain embodiments have been described, these embodiments have been presented by way of example only, and are not intended to limit the scope of the disclosures. Indeed, the novel methods and apparatuses described herein may be embodied in a variety of other forms; furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A gas supply apparatus equipped with a processing container for performing a film forming process for an object to be processed, comprising:
a raw material gas supply system configured to supply a raw material gas carried with a carrier gas into the processing container;
a raw material storage tank having a gas inlet for introducing the carrier gas and a gas outlet connected to a gas passage through which the raw material gas carried with the carrier gas flows, and configured to store a liquid raw material;
a main heating unit configured to heat a bottom and sides of the raw material storage tank to generate the raw material gas;
a ceiling heating unit configured to heat a ceiling portion of the raw material storage tank;
a main temperature measurement unit configured to measure a temperature of a region in which the main heating unit is disposed;
a ceiling temperature measurement unit configured to measure a temperature of a region in which the ceiling heating unit is disposed;
a liquid phase temperature measurement unit configured to measure a temperature of the liquid raw material stored in the raw material storage tank;
a vapor phase temperature measurement unit configured to measure a temperature of a vapor phase portion in the upper part of the raw material storage tank;
a level measurement unit configured to measure a liquid level of the liquid raw material; and
a temperature control unit configured to control the main heating unit and the ceiling heating unit,
wherein the temperature control unit is operated to perform a first process of determining whether to proceed to a second process based on a measurement of the main temperature measurement unit, a measurement of the liquid phase measurement unit, and a predetermined set temperature, and, if it is determined not to proceed to the second process, controlling the main heating unit and the ceiling heating unit based on the set temperature, and the second process of obtaining a control temperature based on measurements of the main temperature measurement unit, the liquid phase temperature measurement unit, the vapor phase temperature measurement unit and the level measurement unit, and controlling the main heating unit and the ceiling heating unit based on the control temperature.

2. The gas supply apparatus of claim 1, wherein the temperature control unit controls the first process to proceed to the second process if a difference between the set temperature and each of the measurements of the main temperature measurement unit and the liquid phase temperature measurement unit falls within a predetermined range in the first process.

3. The gas supply apparatus of claim 2, wherein the predetermined range is equal to or less than 5 degrees C.

4. The gas supply apparatus of claim 1, wherein the temperature control unit controls the main heating unit and the ceiling heating unit such that the control temperature approaches and becomes equal to the set temperature in the second process.

5. The gas supply apparatus of claim 1, wherein the measurement of the level measurement unit is predefined as a position correction value in the temperature control unit.

6. The gas supply apparatus of claim 5, wherein the position correction value falls within a range of equal to or less than the maximum difference between the measurement of the vapor phase temperature measurement unit and the measurement of the liquid phase temperature measurement unit.

7. The gas supply apparatus of claim 5, wherein the temperature control unit is configured to obtain the control temperature according to the following equation:
CP×ITC1+M
where, CP represents the control temperature, ITC1 the measurement of the vapor phase temperature measurement unit and M the position correction value.

8. The gas supply apparatus of claim 1, wherein the temperature control unit is configured to obtain a temperature difference factor depending on a difference between the measurement of the vapor phase temperature measurement unit and the measurement of the liquid phase temperature measurement unit in the second process, and control the ceiling heating unit with a amount of power reduced by the temperature difference factor as a power ratio.

9. The gas supply apparatus of claim 8, wherein the temperature control unit sets the temperature difference factor to “1” if each of the measurements of the vapor phase temperature measurement unit and the liquid phase temperature measurement unit is larger than a predetermined value, and drives the temperature difference factor N according to the following equation if the each measurement is equal to or less than the predetermined value,
N=(ITC2−ITC1)/Y
where, N represents the temperature difference factor, ITC1 represents the measurement of the vapor phase temperature measurement unit, ITC2 represents the measurement of the liquid phase temperature measurement unit and Y represents the maximum difference between the measurement of the vapor phase temperature measurement unit and the measurement of the liquid phase temperature measurement unit.

10. The gas supply apparatus of claim 1, wherein the temperature control unit further determines whether a difference between the set temperature and the measurement of the liquid phase temperature measurement unit falls within the predetermined range in the second process.

11. The gas supply apparatus of claim 1, wherein the liquid raw material is one selected from a group consisting of ZrCp(NMe₂)₃[cyclopentadienyl-tris(dimethylamino) zirconium], Zr(MeCp)(NMe₂)₃[methylcyclopentadienyl-tris(dimethylamino) zirconium], Ti(MeCp)(NMe₂)₃[methylcyclopentadienyl-tris(dimethylamino) titanium], tetrakis(dimethylamino) hafnium, trimethylaluminum (TMA), tetrakisdimethylaminohafnium (TDMAH), tetrakisethylmethylaminohafnium (TEMAH), tetrakisethylmethylaminozirconium (TEMAZ) and tetrakisdimethylaminotitanium (TDMAT).

12. A film forming apparatus for performing a film forming process for an object to be processed, comprising:
an evacuatable processing container;
a holding unit configured to hold the object to be processed within the processing container;
a heating unit configured to heat the object to be processed; and
the gas supply apparatus of claim 1.
